(19) United States
(12) Patent Application Publication
(10) Pub. No.: US 2025/0201737 A1
(43) Pub. Date: Jun. 19, 2025

(54) SEMICONDUCTOR CHIP AND SEMICONDUCTOR COMPONENT

(71) Applicant: XIAMEN SAN'AN INTEGRATED CIRCUIT CO., LTD., Xiamen (CN)

(72) Inventors: Houngchi WEI, Xiamen (CN); Zihan GUO, Xiamen (CN); Peng WANG, Xiamen (CN); Sihang HONG, Xiamen (CN); Yue WANG, Xiamen (CN); Zhenzhen YU, Xiamen (CN)

(21) Appl. No.: 18/679,505

(22) Filed: May 31, 2024

(30) Foreign Application Priority Data
Dec. 18, 2023 (CN) 2023117434933

(51) Int. Cl. H01L 23/60; H01L 23/00; H01L 23/58

(52) U.S. Cl. CPC H01L 23/60; H01L 23/562; H01L 23/564; H01L 23/585

(57) ABSTRACT

A semiconductor chip includes: a protective seal ring and a high-potential area. The protective seal ring is disposed at a periphery of the semiconductor chip, and the high-potential area is disposed in the protective seal ring. The semiconductor chip further includes a grounding protection structure, which is disposed between the high-potential area and the protective seal ring. The grounding protection structure is configured to prevent strong local electric field generated between the high-potential area and the protective seal ring, thereby avoiding reliability failure on the semiconductor chip caused by electrical stress.

### TECHNICAL FIELD

The disclosure relates to the technical field of semiconductor manufacturing, and more particularly to a semiconductor chip and a semiconductor component.

### BACKGROUND

With the development of semiconductor industry, a protective seal ring is used to alleviate stress generated at a cutting edge and to prevent water vapor from entering. The protective seal ring mainly plays a role in buffering and protection, and is not related to layout and design of an internal circuit. However, in a current process of verifying an actual product, it is found that coupling between the protective seal ring and the internal circuit can have unpredictable effects on reliability of the overall semiconductor chip. For example, a strong potential difference can be generated between the protective seal ring and a high-potential area, leading to an electromagnetic induction between the high-potential area and the metal of the protective seal ring. The electromagnetic induction causes rising of local electrical stresses and promotes electrochemical reactions, which eventually leads to an intrusion of the water vapor and causes failure on the corresponding semiconductor component.

Therefore, how to prevent the strong potential difference generated between the protective seal ring and the high-potential area, thereby avoiding the failure on the semiconductor component, has become one of urgent technical problems that engineers in the related art need to solve.

It should be noted that the information disclosed in the background is only intended to enhance an overall understanding of the disclosure. Therefore, the information should not be regarded as acknowledging or implying that the information constitutes the related art that is already known to those skilled in the related art.

### SUMMARY

The disclosure provides a semiconductor chip, which includes: a protective seal ring and a high-potential area. The protective seal ring is disposed at a periphery of the semiconductor chip and the high-potential area is disposed in the protective seal ring. The semiconductor chip is provided with a grounding protection structure thereon; and the grounding protection structure is disposed between the high-potential area and the protective seal ring.

The disclosure further provides a semiconductor component, which can adopt the semiconductor chip as described in any one of the above embodiments.

The semiconductor chip and the semiconductor component provided in the embodiments of the disclosure can effectively prevent strong local electric field generated between the high-potential area and the protective seal ring by providing the grounding protection structure between the high-potential area and the protective seal ring, thereby avoiding reliability failure on the semiconductor chip caused by the electrical stress.

Other features and beneficial effects of the disclosure will be described in the following description, and some technical features and beneficial effects can be clearly obtained from the specification or understood through an implementation mode of the disclosure.

### BRIEF DESCRIPTION OF DRAWINGS

In order to provide a clearer explanation of embodiments of the disclosure or the technical solutions in the related art, a brief introduction will be made to the attached drawings required in the embodiments or the description of the related art. It is evident that some of the attached drawings in the following description are used to describe some of the embodiments of the disclosure. For those skilled in the related art, other attached drawings can be obtained based on the described attached drawings without creative labor.

FIG. 1 illustrates a schematic structural diagram of a semiconductor chip according to an embodiment 1 of the disclosure.

FIG. 2 illustrates a partial enlarged schematic diagram of an A area in FIG. 1.

FIG. 3 illustrates a schematic diagram of a longitudinal section cut from an F-F line shown in FIG. 1.

FIG. 4 illustrates a schematic structural diagram of a grounding protection structure according to another embodiment of the disclosure.

FIG. 5 illustrates a schematic structural diagram of a semiconductor chip according to an embodiment 2 of the disclosure.

FIG. 6 illustrates a schematic structural diagram of a semiconductor chip according to an embodiment 3 of the disclosure.

FIG. 7 illustrates a schematic structural diagram of a semiconductor chip according to an embodiment 4 of the disclosure.

FIG. 8 illustrates a schematic structural diagram of a semiconductor chip according to an embodiment 5 of the disclosure.

FIG. 9 illustrates a schematic structural diagram of a semiconductor chip according to an embodiment 6 of the disclosure.

FIG. 10 illustrates a schematic structural diagram of a semiconductor chip according to an embodiment 7 of the disclosure.

FIG. 11 illustrates a schematic structural diagram of a semiconductor chip according to an embodiment 8 of the disclosure.

FIG. 12 illustrates a schematic structural diagram of a semiconductor chip according to an embodiment 9 of the disclosure.

FIG. 13 illustrates a schematic structural diagram of a semiconductor chip according to an embodiment 10 of the disclosure.

### Description of Reference Signs are as Follows

10—protective seal ring;
20—high potential area; 21—high potential component; 22—high potential circuit; 23—passive component;
30—grounding protection structure; 31—back metal grounding layer; 32—grounding through-hole; 33—metal circuit layer; 34—conductive column; 35—grounding terminal structure;
40—dielectric layer; 41—connection via; 45—epitaxial layer;
50—substrate; and
L1, L2, and L3—distance; W1—width of grounding protection structure.

### DETAILED DESCRIPTION OF EMBODIMENTS

In order to clarify the objective, the technical solution, and the advantages of the embodiments of the disclosure, the following will provide a clear and complete description of the technical solution in the embodiments of the disclosure in conjunction with the attached drawings. Apparently, the described embodiments are a part of the embodiments of the disclosure, not all of the embodiments; and the technical features designed in different embodiments of the disclosure described below can be combined with each other as long as they do not conflict with each other. Based on the embodiments in the disclosure, all of other embodiments obtained by those skilled in the related art without creative labor fall within the protection of the scope of the disclosure.

In the description of the disclosure, it should be understood that terms such as “center”, “transverse”, “up”, “down”, “left”, “right”, “vertical”, “horizontal”, “top”, “bottom”, “inside”, “outside”, etc. indicate that an orientation or a position relationship is based on the orientation or the position relationship illustrated in the attached drawings, only for the convenience of describing the disclosure and simplifying the description, rather than indicating or implying that a device or a component referred to must have a specific orientation, or be constructed and operated in a specific orientation. Therefore, the terms cannot be understood as a limitation to the disclosure. In addition, terms such as “first” and “second” are only descriptive and cannot be understood as indicating or implying relative importance or implying a quantity of the technical features indicated. Therefore, the technical features with the limitation of “first” and “second” can explicitly or implicitly include one or more of the technical features. In the description of the disclosure, unless otherwise specified, “multiple” means two or more. In addition, a term “including” and any variations thereof mean “at least including”.

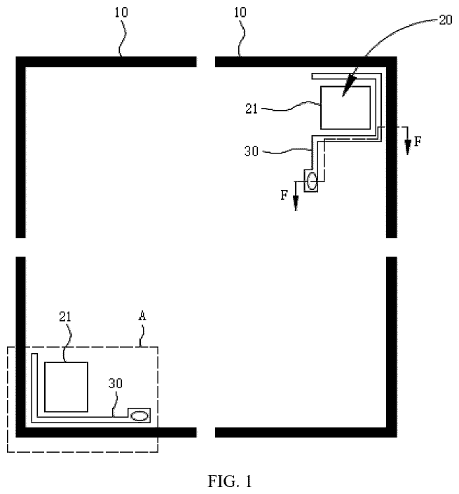

With reference to FIGS. 1-2, FIG. 1 illustrates a schematic structural diagram of a semiconductor chip according to an embodiment 1 of the disclosure; and FIG. 2 illustrates a partial enlarged schematic diagram of an A area in FIG. 1. In order to achieve at least one of the advantages or more, an embodiment of the disclosure provides a semiconductor chip. As shown in the attached drawings, the semiconductor chip can at least include a protective seal ring 10 and a high-potential area 20.

The protective seal ring 10 is disposed at a periphery of the semiconductor chip. The protective seal ring 10 is used to protect local circuits inside the semiconductor chip, such as wire-bond pads, metal connections, switches, etc., thereby enhancing ability against biased highly accelerated stress test (bHAST) of the semiconductor chip. HAST refers to the highly accelerated stress test, and the bHAST refers to the biased highly accelerated stress test. A shape of the protective seal ring 10 is non-closed, meaning that the protective seal ring 10 commands an opening and should not be completely closed.

The high-potential area 20 is disposed in the protective seal ring 10. The high-potential area 20 refers to an area possessing high-potential components, metal connections, and other components in a circuit. In some cases, the high potential refers to a potential where the absolute value of static bias voltage is higher than a certain potential. Taking the material of gallium arsenide (GaAs) as an example, the absolute value of its static bias voltage is between 3-5 volts (V), which can be considered as the high potential. In some cases, the high potential can also refer to all non-zero static bias potentials except from logic input potentials and groundings.

The high-potential area 20 includes a high-potential component 21 and/or a high-potential circuit. As shown in FIG. 1, the high-potential area 20 includes the high-potential component 21. The high-potential component 21 can be, for example, a pad for wire-bonding/copper pillar. In the current design of a semiconductor chip, due to considerations such as wire bond and area utilization, the high-potential area 20, as a high-potential power supply port, is often arranged close to the periphery of the semiconductor chip, in which case very close to the boundary of the protective seal ring 10. The above arrangement results in strong electrical stress generated between the high-potential component 21 as well as the high-potential circuit 22, and the protective seal ring 10 during reliability testing, which promotes interface electrochemical reaction and allows water vapor intrude into the semiconductor chip more easily, then eventually leads to a failure in the semiconductor chip.

To solve the problem above, the disclosure further includes a grounding protection structure 30 disposed on the semiconductor chip, which is used for the grounding operation. The grounding protection structure 30 is disposed between the high-potential area 20 and the protective seal ring 10, and does not directly contact with the high-potential area 20 as well as the protective seal ring 10. Moreover, the grounding protection structure 30 is used to prevent strong local electric field generated between the high-potential area 20 and the protective seal ring 10, thereby avoiding reliability failure on the semiconductor chip caused by the electrical stress and induced vapor invasion. The grounding protection structure 30 is used for the grounding operation and is not connected to the high-potential area 20 or the protective seal ring 10, so that the electric field can be shielded at the grounding protection structure 30, thereby eliminating the potential difference between the high-potential area 20 and the protective seal ring 10. Moreover, the grounding protection structure 30 arranged for the high-potential area 20 can widen the distance between the high-potential area 20 and the protective seal ring 10, providing additional protection and better preventing from the invasion of the water vapor.

The grounding protection structure 30 is not a functional circuit component, which means that the grounding protection structure 30 works as a structure preventing failure only and does not have any circuit functions other than preventing the vapor invasion. It does not mean that the grounding protection structure 30 is not a part of the chip. For example, the grounding protection structure 30 is not connected to components other than a grounding through-hole/copper pillar, nor does it paly the function other than preventing the failure on the edge of semiconductor chip during the circuit works, especially the bHAST test. Moreover, the grounding protection structure 30 will not be electrically connected to components disposed in the high-potential area 20, the grounding protection structure 30 will not be electrically connected to the protective seal ring 10, either.

In a top view, in other words, as viewed from the top of the semiconductor chip which includes the protective seal ring 10, as shown in FIG. 1, the grounding protection structure 30 is disposed to surround at least one side of the high-potential area 20. The description of surrounding at least one side of the high-potential area 20 can be understood as follows: in FIG. 1, the high-potential component 21 disposed in the high-potential area 20 is a square solder pad for wire-bonding; and the grounding protection structure 30 only needs to surround one side of the square solder pad to shield the electric field, and the side that is surrounded should be the side disposed closest to the protective seal ring 10. However, the disclosure is not limited to the square shape above. When the shape of the component 21 within the high-potential area 20 is a circle, ellipse, or some irregular shape, sides of the high-potential component 21 may be infinitely multiple (i.e., the circle). Therefore, it is possible to use a method that surrounds a periphery of the high-potential area 20, namely that the grounding protection structure 30 surrounds at least 1/10 of the periphery of the high-potential area 20. In another embodiment, in an area where the distance between the high-potential area 20 and the protective seal ring 10 is within 15 micrometers (μm), the grounding protection structure 30 can be inserted to shield the electric field. When the distance between the high-potential area 20 and the protective seal ring 10 is greater than 15 μm, the large distance itself will be enough to reduce the reliability failure on the semiconductor chip caused by the electrical stress, in which case there is no need to set up the grounding protection structure 30 to shield the electric field. However, the large distance can also lead to a decrease in the area utilization of the semiconductor chip, thereby increasing chip cost.

In all embodiments, the grounding protection structure 30 does not completely surround (i.e., enclose) the periphery of the high-potential area 20, which means that the grounding protection structure 30 should not in a completely enclosed form. If it is completely enclosed and surrounds the high-potential area 20, it will lead to metal residue during manufacturing, which will seriously affect the wafer production.

From the top view, a minimum distance L1 between the high-potential area 20 and the protective seal ring 10 can be in a range of 5 to 10 μm. If the distance L1 is too small (such as less than 5 μm), it will squeeze the reserved space for the grounding protection structure 30, which will weaken the shielding function of the grounding protection structure 30. Also, this can easily lead to metal wire adhesion. Moreover, if the distance L1 is too large (such as greater than 10 μm), it will reduce the efficiency of the area utilization for the semiconductor chip.

From the top view, a minimum distance L2 between the grounding protection structure 30 and the high-potential area 20 can be in a range of 2 to 5 μm. If the distance L2 is too small (such as less than 2 μm), it is not conducive to making the grounding protection structure 30; and if the distance L2 is too large (such as greater than 5 μm), it will reduce the effectiveness of the grounding protection structure 30 and reduce the efficiency of the area utilization for the semiconductor chip.

From the top view, a minimum distance L3 between the grounding protection structure 30 and the protective seal ring 10 should be in a range of 3 to 8 μm. If the distance L3 is too small (such as less than 3 μm), it is not conducive to manufacturing the grounding protection structure 30; and if the distance L3 is too large (such as greater than 8 μm), it will reduce the effect of the grounding protection structure 30 and moreover reduce the efficiency of the area utilization. A width W1 of the grounding protection structure 30 can be in a range of 4-10 μm. If the width W1 is too small (such as less than 4 μm), it is not conducive to manufacturing the grounding protection structure 30; and if the width W1 is too large (such as greater than 10 μm), it will reduce the efficiency of the area utilization for the semiconductor chip.

In some embodiments, the grounding protection structure 30 is a single-ended grounded open metal circuit, that is, the grounding protection structure 30 only has one end connected to the grounding structure, and does not work as a functional circuit component. It cannot form a direct-current (DC) or alternating-current (AC) conductive path. In addition, the grounding protection structure 30 can also be designed by using popular grounding structures in different processes. The following provides two structures in view of the single-ended grounded open metal circuit.

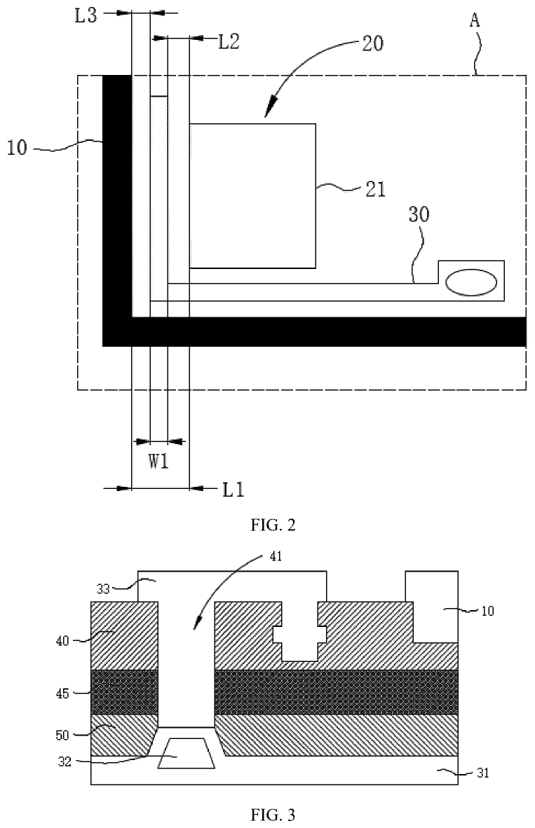

As shown in FIG. 3, the grounding protection structure 30 includes: a back metal grounding layer 31, a grounding through-hole 32, and at least one metal circuit layer 33. The semiconductor chip further includes: a dielectric layer 40, an epitaxial layer 45, and a substrate 50. The epitaxial layer 45 is disposed on the substrate 50, and the dielectric layer 40 is disposed to cover on the epitaxial layer 45. The dielectric layer 40 defines a connection via 41, which penetrates from the dielectric layer 40 to the substrate 50.

The metal circuit layer 33 (also referred to the at least one metal circuit layer) is disposed on the dielectric layer 40, the back metal grounding layer 31 is disposed below the substrate 50, the metal circuit layer 33 is connected to the back metal grounding layer 31 through the connection via 41, and the grounding through-hole 32 is defined in the back metal grounding layer 31. The dielectric layer 40 is made by at least one of the following materials such as silicon oxide, silicon nitride, and polyimide, while the substrate 50 can be made by the following materials such as GaAs, indium phosphide (InP), gallium nitride (GaN), silicon (Si), etc.

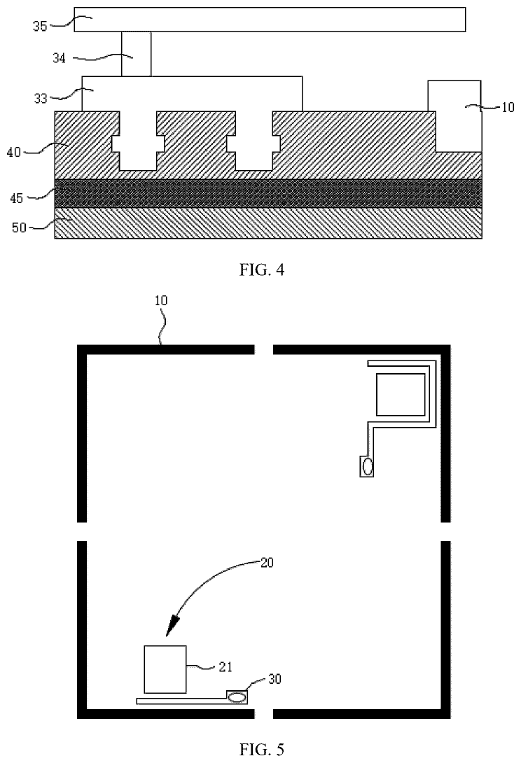

With reference to FIG. 4, the grounding protection structure 30 includes: at least one metal circuit layer 33, a conductive column 34, and a grounding terminal structure 35. The semiconductor chip further includes: a dielectric layer 40, an epitaxial layer 45, and a substrate 50. The epitaxial layer 45 is disposed on the substrate 50, and the dielectric layer 40 is disposed to cover on the epitaxial layer 45. The metal circuit layer 33 is connected to the dielectric layer 40, the conductive column 34 is connected to the metal circuit layer 33, and the grounding terminal structure 35 is connected to the conductive column 34. For example, the conductive column 34 can be a conductive copper column. The substrate 50 can be made by the following materials such as GaAs, InP, GaN, Si, etc. The grounding terminal structure 35, for example, can be a flip structure that is connected to a substrate grounding terminal.

With reference to FIG. 5, it illustrates a schematic structural diagram of a semiconductor chip according to an embodiment 2 of the disclosure. Compared to the semiconductor chip disclosed in the embodiment 1 illustrated by FIG. 1, a main difference in view of the semiconductor chip illustrated in the embodiment 2 is that the distance between the high-potential area 20 in a lower left corner of FIG. 5 and the left side of the protective seal ring 10 is too large, so that there is no need to set the grounding protection structure 30. However, the grounding protection structure 30 should be set only at the small distance between the high-potential area 20 and the protective seal ring 10, which can prevent the strong local electric field generated between the high-potential area 20 and the protective seal ring 10.

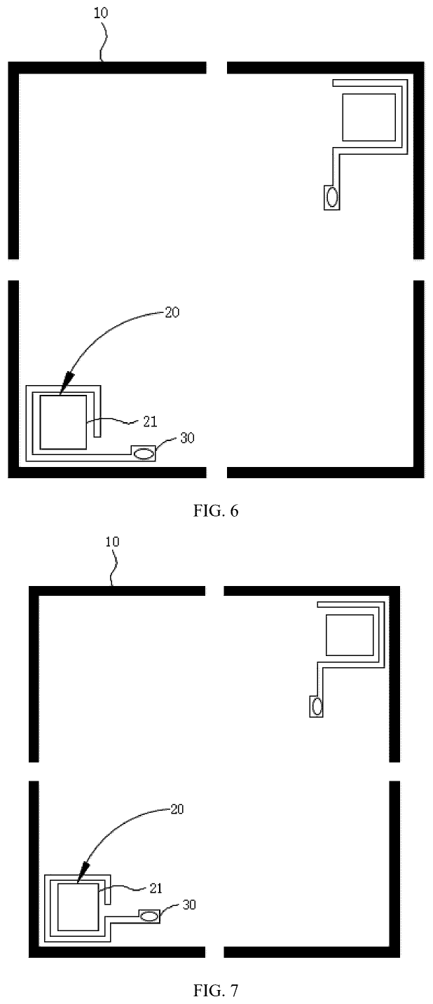

With reference to FIG. 6, it illustrates a schematic structural diagram of a semiconductor chip according to the embodiment 3 of the disclosure. Compared to the semiconductor chip disclosed in the embodiment 1 illustrated by FIG. 1, a main difference in view of the semiconductor chip illustrated in the embodiment 3 is that the high-potential area 20 in the lower left corner of FIG. 6 have more sides surrounded by the grounding protection structure 30, that is, the grounding protection structure 30 surrounds more than ¾ of the periphery of the high-potential area 20 to prevent the strong local electric field generated between the high-potential area 20 and the protective seal ring 10, thereby improving the reliability of the semiconductor chip.

With reference to FIG. 7, it illustrates a schematic structural diagram of a semiconductor chip according to an embodiment 4 of the disclosure. Compared to the semiconductor chip disclosed in the embodiment 3 illustrated by FIG. 6, a main difference in view of the semiconductor chip illustrated in the embodiment 4 is that a grounding point of the grounding protection structure 30 can be disposed in an area further facing away from the protective seal ring 10.

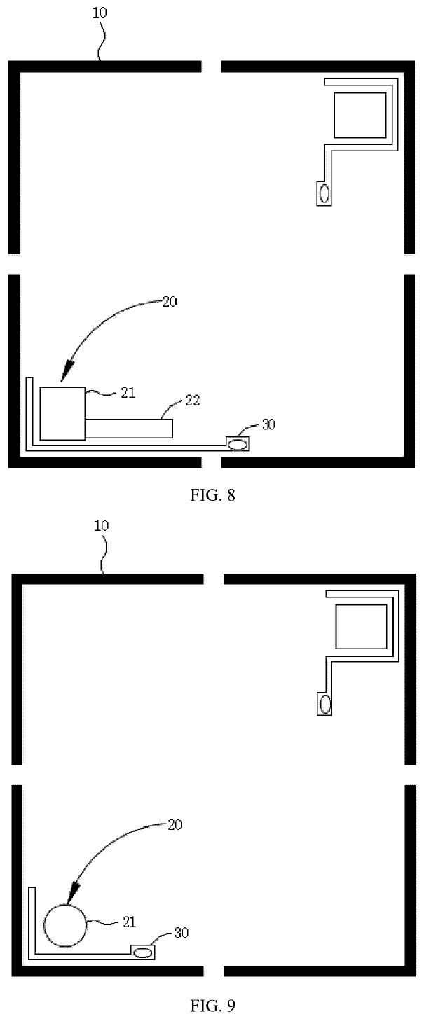

With reference to FIG. 8, it illustrates a schematic structural diagram of a semiconductor chip according to an embodiment 5 of the disclosure. Compared to the semiconductor chip disclosed in the embodiment 1 illustrated by FIG. 1, a main difference in view of the semiconductor chip illustrated in the embodiment 5 is that the high-potential area 20 further includes a high-potential circuit 22, which is connected to the high-potential component 21. The grounding protection structure 30 surrounds the high-potential circuit 22.

With reference to FIG. 9, it illustrates a schematic structural diagram of a semiconductor chip according to the embodiment 6 of the disclosure. Compared to the semiconductor chip disclosed in the embodiment 1 illustrated by FIG. 1, a main difference in view of the semiconductor chip illustrated in the embodiment 6 is that the shape of the high-potential component 21 in the lower left corner of FIG. 9 is a circle, and the grounding protection structure 30 encloses the high-potential component 21. In an illustrated embodiment, the grounding protection structure 30 can be set in an arc shape to surround the high-potential component 21.

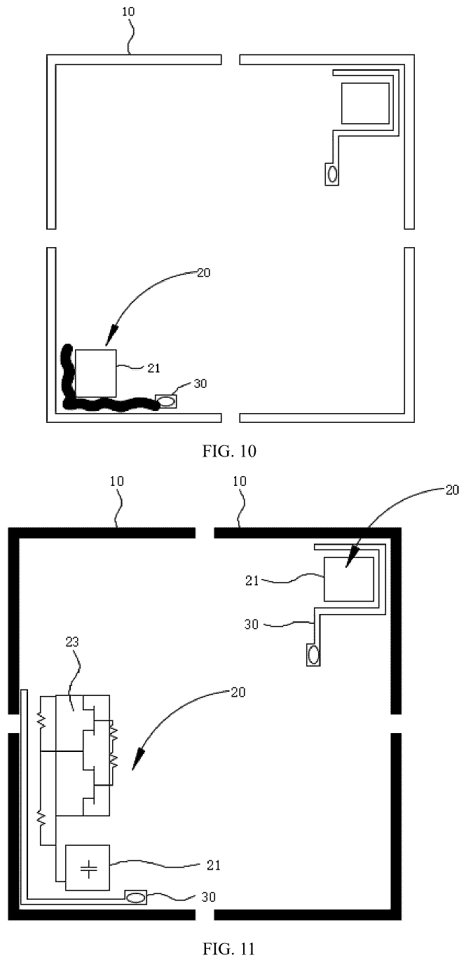

With reference to FIG. 10, it illustrates a schematic structural diagram of a semiconductor chip according to the embodiment 7 of the disclosure. Compared to the semiconductor chip disclosed in the embodiment 1 illustrated by FIG. 1, a main difference in view of the semiconductor chip illustrated in the embodiment 7 is that the grounding protection structure 30 is not limited to straight lines, but can also be arc-shaped, curved, etc. When the grounding protection structure 30 is disposed between the high-potential area 20 and the protective seal ring 10, the electric field can be shielded.

With reference to FIG. 11, it illustrates a schematic structural diagram of a semiconductor chip according to the embodiment 8 of the disclosure. Compared to the semiconductor chip disclosed in the embodiment 1 illustrated by FIG. 1, a main difference in view of the semiconductor chip illustrated in the embodiment 8 is that the high-potential area 20 in the lower left corner of FIG. 11 not only includes the high-potential component 21, but also includes a passive component 23 connected to the high-potential component 21, such as a resistor, a capacitor, or an inductor. In addition, in some embodiments, the high-potential area 20 may also include an active device connected to the high-potential component 21. For example, the active device can be a bipolar junction transistor (BJT), a high electron mobility transistor (HEMT), or a metal oxide semiconductor field effect transistor (MOSFET).

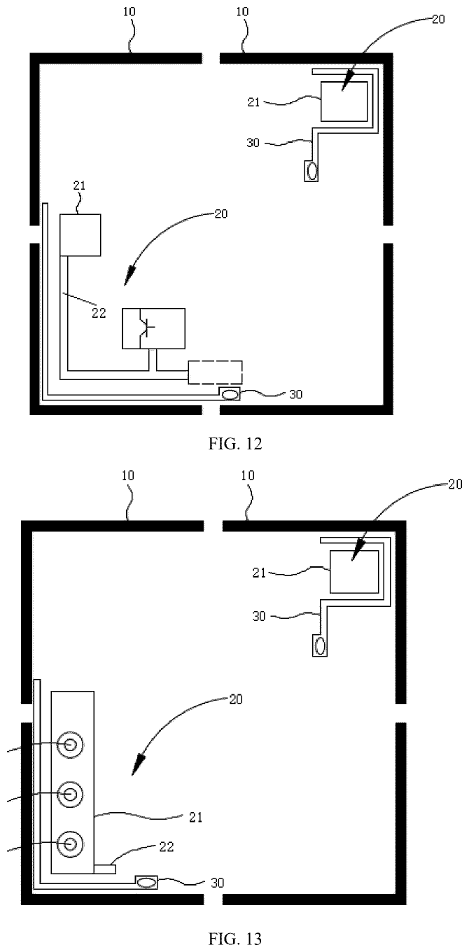

With reference to FIG. 12, it illustrates a schematic structural diagram of a semiconductor chip according to the embodiment 9 of the disclosure. Compared to the semiconductor chip disclosed in the embodiment 1 illustrated by FIG. 1, a main difference in view of the semiconductor chip illustrated in the embodiment 9 is that the high-potential area 20 in the lower left corner of FIG. 12 not only includes the high-potential component 21, but also includes a high-potential circuit 22 connected to the high-potential component 21 (such as an external power supply lead wire), as well as certain components connected at an end of the high-potential circuit 22 (indicated by dashed lines in FIG. 12).

With reference to FIG. 13, it illustrates a schematic structural diagram of a semiconductor chip according to the embodiment 10 of the disclosure. Compared to the semiconductor chip disclosed in the embodiment 1 illustrated by FIG. 1, a main difference in view of the semiconductor chip illustrated in the embodiment 10 is that the high-potential component 21 in the lower left corner of FIG. 13 includes multiple high-potential solder pads, and the high-potential area 20 also includes: a high-potential circuit 22 exerted with a high-potential/high-power signal, which is connected to the high-potential component 21.

Namely, the high-potential area 20 includes the following situations: (1) a static offset pad or a pin; (2) a high-potential power supply wire; (3) a capacitor, a resistor, or an inductor that is connected to a high-potential power supply pad; (4) an active component port connected to a power supply circuit. In addition, the high-potential area 20 can include: a metal circuit, a passive component, or an electrode pad that are capable of passing a high-power AC signal in a circuit.

The semiconductor chip can be applied to the active device and the passive device. For example, the active device can be one of the nodes of a BJT, a HEMT, a pseudomorphic high electron mobility transistor (pHEMT), or a MOSFET; and the passive device can be a resistor, a capacitor, and an inductor.

The disclosure also provides a semiconductor component, which can adopt the semiconductor chip as described in any of the above embodiments.

In summary, the semiconductor chip and the semiconductor component provided in the embodiments of the disclosure can effectively prevent the strong local electric field generated between the high-potential area 20 and the protective seal ring 10 by setting the grounding protection structure 30 between the high-potential area 20 and the protective seal ring 10, thereby avoiding the reliability failure on the semiconductor chip caused by the electrical stress.

In addition, those skilled in the art should understand that although there are many problems in the related art, each embodiment or technical solution of the disclosure can be improved in only one or a few aspects, without having to simultaneously solve all the technical problems listed in the related art or background. Those skilled in the related art should understand that any content not mentioned should not be used as a limitation to the disclosure.

Finally, it should be noted that the above embodiments are only used to illustrate the technical solutions of the disclosure, and not to limit the disclosure. Although the disclosure has been described in detail with reference to the aforementioned embodiments, those skilled in the related art should understand that they can still modify the technical solutions recorded in the aforementioned embodiments, or equivalently replace some or all of the technical features. And these modifications or replacements do not make the essence of the corresponding technical solution deviate from the scope of the technical solution of the various embodiments of the disclosure.

What is claimed is:

1. A semiconductor chip, comprising: a protective seal ring and a high-potential area;
wherein the protective seal ring is disposed at a periphery of the semiconductor chip, and the high-potential area is disposed in the protective seal ring; and
wherein the semiconductor chip is provided with a grounding protection structure thereon; and the grounding protection structure is disposed between the high-potential area and the protective seal ring.

2. The semiconductor chip as claimed in claim 1, wherein in a top view, the grounding protection structure is disposed to surround at least one side of the high-potential area.

3. The semiconductor chip as claimed in claim 1, wherein in a top view, the grounding protection structure does not enclose a periphery of the high-potential area.

4. The semiconductor chip as claimed in claim 1, wherein in a top view, a minimum distance between the high-potential area and the protective seal ring is in a range of 5-10 micrometers (μm).

5. The semiconductor chip as claimed in claim 1, wherein in a top view, a minimum distance between the grounding protection structure and the high-potential area is in a range of 2-5 μm.

6. The semiconductor chip as claimed in claim 1, wherein in a top view, a minimum distance between the grounding protection structure and the protective seal ring is in a range of 3-8 μm.

7. The semiconductor chip as claimed in claim 1, wherein a width of the grounding protection structure is in a range of 4-10 μm.

8. The semiconductor chip as claimed in claim 1, wherein the grounding protection structure is a single-ended grounded open metal circuit.

9. The semiconductor chip as claimed in claim 1, wherein the grounding protection structure comprises: a back metal grounding layer, a grounding through-hole, and at least one metal circuit layer;
wherein the semiconductor chip further comprises: a dielectric layer, an epitaxial layer, and a substrate; and
wherein the epitaxial layer is disposed on the substrate, and the dielectric layer is disposed to cover on the epitaxial layer; the dielectric layer defines a connection via, and the connection via penetrates from the dielectric layer to the substrate; the at least one metal circuit layer is disposed on the dielectric layer, the back metal grounding layer is disposed below the substrate, the at least one metal circuit layer is connected to the back metal grounding layer through the connection via, and the grounding through-hole is defined in the back metal grounding layer.

10. The semiconductor chip as claimed in claim 1, wherein the grounding protection structure comprises: at least one metal circuit layer, a conductive column, and a grounding terminal structure;
wherein the semiconductor chip further comprises: a dielectric layer, an epitaxial layer, and a substrate; and
wherein the epitaxial layer is disposed on the substrate, and the dielectric layer is disposed to cover on the epitaxial layer; the at least one metal circuit layer is connected to the dielectric layer, the conductive column is connected to the at least one metal circuit layer, and the grounding terminal structure is connected to the conductive column.

11. The semiconductor chip as claimed in claim 3, wherein the grounding protection structure at least surrounds ¾ of the periphery of the high-potential area.

12. The semiconductor chip as claimed in claim 1, wherein the high-potential area comprises: a high-potential component and/or a high-potential circuit.

13. The semiconductor chip as claimed in claim 12, wherein the high-potential component comprises an electrode pad.

14. The semiconductor chip as claimed in claim 1, wherein the semiconductor chip is applied to prepare a bipolar junction transistor (BJT), a high electron mobility transistor (HEMT), a pseudomorphic high electron mobility transistor (pHEMT), a metal oxide semiconductor field effect transistor (MOSFET), a resistor, a capacitor, and an inductor.

15. The semiconductor chip as claimed in claim 1, wherein the grounding protection structure is not a functional circuit component.

16. The semiconductor chip as claimed in claim 1, wherein a shape of the protective seal ring is non-closed.

17. The semiconductor chip as claimed in claim 1, wherein a shape of the grounding protection structure is linear, arc-shaped, or curved.

18. The semiconductor chip as claimed in claim 1, wherein the high-potential area comprises: a static offset pad or a pin; or a high-potential power supply lead wire; or a capacitor, a resistor, and an inductor that are connected to a high-potential power supply pad; or an active component port connected to a power supply circuit.

19. The semiconductor chip as claimed in claim 1, wherein the high-potential area comprises: a metal circuit, a passive component, and an electrode pad that are capable of passing an alternating-current (AC) signal in a circuit.

20. A semiconductor component, comprising: the semiconductor chip as claimed in claim 1.
